(19) United States
(12) Patent Application Publication
(10) Pub. No.: US 2019/0041660 A1
(43) Pub. Date: Feb. 7, 2019

(54) VERTICAL-CAVITY SURFACE EMITTING LASER (VCSEL) ILLUMINATOR FOR REDUCING SPECKLE

(71) Applicant: Intel Corporation, Santa Clara, CA (US)

(72) Inventor: Khaled Ahmed, Anaheim, CA (US)

(73) Assignee: Intel Corporation, Santa Clara, CA (US)

(21) Appl. No.: 16/129,624

(22) Filed: Sep. 12, 2018

(51) Int. Cl. G02B 27/48; G06K 9/20; G06K 9/00; H04N 5/33; H04N 9/31; H01S 5/42; H01S 5/187; H01S 5/183

(52) U.S. Cl. CPC G02B 27/48; G06K 9/2036; G06K 9/00255; H04N 5/33; H01S 5/18394; H01S 5/423; H01S 5/187; H01S 5/18355; H04N 9/3161

(57) ABSTRACT

A vertical cavity surface emitting laser (VCSEL) illuminator for reduced speckle has VCSELs with metalayer polarizers, VCSEL arrays with varying aperture sizes, or both.

### BACKGROUND

Projectors or illuminators are often used to project infra-red light (about 700 to 2500 nm wavelength for near-infra-red (NIR)) onto an object and then use a sensor (or camera) to detect the light reflecting from the object in order to form images of the object. The images then may be used for a number of applications including biometric detection for security authorization purposes such as with face detection or iris scanning recognition. These detection systems may be used to authorize a user to unlock many different objects such as computers, computer files, other electronic devices, or systems that trigger the unlocking of a physical device such as a door lock to name a few examples. Such NIR systems also may be used for eye tracking and other object detection operations such as with motion detection related-games or artificial intelligence (AI), computer vision, and so forth. In these systems, the sensed reflections from the NIR illuminator are used to form an IR or NIR image with specific characteristics needed to perform the desired detection or to use the image for other applications. The cameras that generate images of a user's face to use the image to authorize access to something may be referred to herein as a face login camera.

The conventional NIR illuminator devices use LED illuminators. These conventional illuminators, however, often suffer from a loss of IR signal towards the edges and corners of the image due to fall off (e.g., reduced radiation intensity) of the illuminator, lens shading, image sensor aperture limitations (where the aperture at the camera sensor is not wide enough to capture sufficient light near the edges of the aperture), and angular effects of the IR band pass filter at the sensor (or camera) that permit too much ambient light into the camera. At the same time, the center of the image may be too bright (too much light intensity or radiation) due to too much concentration of light at the center of the image, and so much so that the center of the image may be washed out by the light intensity.

It has been found that vertical cavity surface-emitting laser (VCSEL) illuminators resolve a number of these issues. The VCSEL provides a smaller and more controlled source of illumination with greater collimation as well as narrower emission wavelengths. This will become more important as time passes because more and more systems will use hybrid cameras (RGB+IR) instead of two separate RGB and IR cameras to reduce cost and save space. A hybrid camera, however, will have fewer IR pixels compared to a separate IR camera. Thus, in order to meet the high quality demands of security applications, the IR image quality will require better infrared illumination that can be provided by the conventional VCSEL.

Specifically, a laser produces light that is inherently narrow band, and when a light source (such as the conventional VCSEL) is coherent such that it emits light at substantially a single wavelength at a single phase, this can result in undesirable, severe, high-contrast speckle that forms blotches and spots on an IR or NIR image sufficiently severe so that it is difficult or even impossible to perform facial or other object detection analysis of the image.

### DESCRIPTION OF THE FIGURES

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is an illustration of a user using an electronic device with a light projection and image capturing system being used for object detection and access authorization;

FIG. 2 is a schematic diagram of an IR light projection and image capture and processing system in accordance with at least one of the implementations described herein;

FIG. 3 is a cross-sectional side view of a vertical cavity surface emitting laser (VCSEL) in accordance with at least one of the implementations herein;

FIG. 4 is a flow chart for emitting light from a VCSEL illuminator in accordance with at least one of the implementations described herein;

FIG. 5 is a pair of graphs showing light intensity transverse modes that can be achieved depending on a single VCSEL diameter according to at least one of the implementations herein;

FIG. 5A is a plan view of an example VCSEL array for at least one of the implementations herein;

FIG. 5B is a simplified top view of an example VCSEL multi-array illuminator according to at least one of the implementations herein;

FIG. 5C is a top view of a single VCSEL array used on the illuminator of FIG. 5B;

FIG. 6 is a flow chart of a method of forming a VCSEL illuminator in accordance with at least one of the implementations herein;

FIG. 7 is a far-field radiation graph showing a batwing (M-shaped) intensity curve in accordance with at least one of the implementations herein;

FIG. 8 is a perspective close-up view of an example metalayer in accordance with at least one of the implementations herein;

FIG. 9 is a simplified side view of the example metalayer of FIG. 8 in accordance with at least one of the implementations herein;

FIG. 10 is a graph of a simulated reflectivity spectrum for a transverse electric (TE) polarizer;

FIG. 11 is a graph of a simulated reflectivity spectrum for a transverse magnetic (TM) polarizer;

FIG. 12 is a perspective view of an arrangement of posts on a metalayer to form parallel polarization in accordance with at least one of the implementations herein;

FIG. 13 is a perspective view of an arrangement of posts on a metalayer to form perpendicular polarization in accordance with at least one of the implementations herein;

FIG. 14 is a simplified top view of another example VCSEL illuminator showing arrays of VCSELs each with a polarizing metalayer in accordance with at least one of the implementations herein;

FIG. 15 is an illustrative diagram of an example light emitting and image processing system;

FIG. 16 is an illustrative diagram of an example system; and

FIG. 17 is an illustrative diagram of an example system, all arranged in accordance with at least some implementations of the present disclosure.

### DETAILED DESCRIPTION

One or more implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

While the following description sets forth various implementations that may be manifested in architectures such as system-on-a-chip (SoC) architectures for example, implementation of the techniques and/or arrangements described herein, other than the specific structure of an illuminator described below, are not restricted to particular architectures and/or computing systems and may be implemented by any architecture and/or computing system for similar purposes. For instance, various architectures employing, for example, multiple integrated circuit (IC) chips and/or packages, and/or various computing devices and/or consumer electronic (CE) devices such as set top boxes, smartphones, televisions, cameras, laptop computers, tablets, and so forth, as well as dedicated access authorization devices either for access to an electronic device or otherwise mounted or placed at a variety of physical locations may implement the techniques and/or arrangements described herein. Further, while the following description may set forth numerous specific details such as logic implementations, types and interrelationships of system components, logic partitioning/integration choices, and so forth, claimed subject matter may be practiced without such specific details. In other instances, some material such as, for example, control structures and full software instruction sequences, may not be shown in detail in order not to obscure the material disclosed herein.

The material disclosed herein, other than the specific structure of the IR illuminator and sensor described below, may be implemented in hardware, firmware, software, or any combination thereof. The material disclosed herein also may be implemented as instructions stored on a machine-readable medium, which may be read and executed by one or more processors. A machine-readable medium may include any medium and/or mechanism for storing or transmitting information in a form readable by a machine (for example, a computing device). For example, a machine-readable medium may include read-only memory (ROM); random access memory (RAM); magnetic disk storage media; optical storage media; flash memory devices; electrical, optical, acoustical or other forms of propagated signals (e.g., carrier waves, infrared signals, digital signals, and so forth), and others. In another form, a non-transitory article, such as a non-transitory computer readable medium, may be used with any of the examples mentioned above or other examples except that it does not include a transitory signal per se. It does include those elements other than a signal per se that may hold data temporarily in a “transitory” fashion such as RAM and so forth.

References in the specification to “one implementation”, “an implementation”, “an example implementation”, and so forth, indicate that the implementation described may include a particular feature, structure, or characteristic, but every implementation may not necessarily include the particular feature, structure, or characteristic. Moreover, such phrases are not necessarily referring to the same implementation. Further, when a particular feature, structure, or characteristic is described in connection with an implementation, it is submitted that it is within the knowledge of one skilled in the art to affect such feature, structure, or characteristic in connection with other implementations whether or not explicitly described herein.

A vertical-cavity surface-emitting laser (VCSEL) illuminator for reducing speckle.

An infra-red (IR) illuminator may be used for biometric detection or other applications. For example, such biometric detection may be related to face recognition or iris illuminators and IR imaging systems including face login and other near infrared (NIR) centric techniques, usages, devices, and the like. Such techniques, usages, devices, and the like may require controlled NIR illumination to generate an image with the specific characteristics needed for face recognition or other usages.

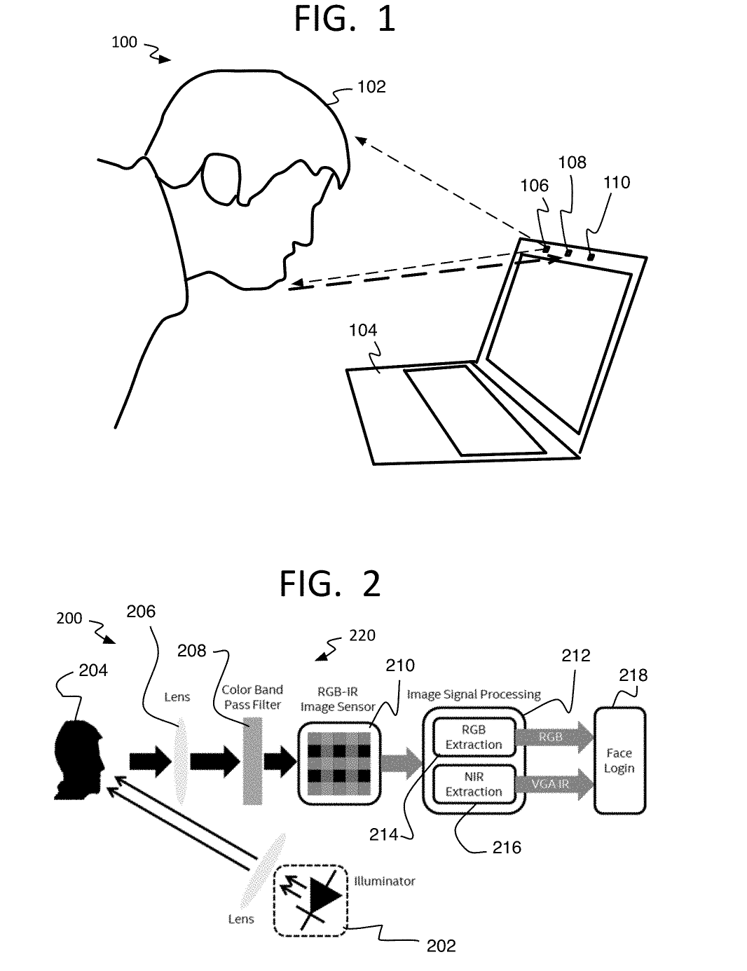

Referring to FIG. 1, an example face login system 100 is shown where a user 102 faces an access authorization device 104, which in this example may be a computer or laptop with an IR illuminator (or projector) 106, and one or more cameras or sensors 108 and 110 that detects light projected from the IR illuminator and reflected from an object 102 to be detected such as the user's face. When one camera is being used, it may be an RGB-IR camera. Such an arrangement was conventionally performed by using an LED illuminator emitting NIR light. Also as mentioned, it has been found that to achieve a more desired radiation distribution pattern (or emission pattern), a vertical-cavity surface emitting laser (VCSEL) illumination source may be used instead of the LED, and which may offer a smaller and more controlled source of illumination with greater collimation as well as narrower emission wavelengths. Also, the VCSEL may provide a reduced emission angle that better matches the camera viewing angle to reduce waste at the outer limits of the angle that is outside the outer (or edge) image emission angle.

The use of the VCSEL, however, (1) results in undesirable, severe, high-contrast speckle, and (2) does not provide desired far-field radiation intensity peaks at the outer image emission angle causing outside edges and corners of an IR image to be too dark and have distorted signal-to-noise ratios that are often desirable for use in object detection. With regard to (1) the speckle, laser (VCSEL) light is inherently narrow band, and when a light source (such as the VCSEL) is coherent, it emits light at substantially a single wavelength at a single phase for example. When this light reflects off a rough surface, multiple paths of various lengths are generated between the illuminator and detector and the light from various paths may interfere with each other in the detector, combining in constructive or destructive manners. This combining works to form patches of higher intensity light and lower intensity light due to the resulting constructive interference where light waves combine, and deconstructive interference where light waves subtract from each other. In an image detector with a finite camera aperture such as on camera sensors, and which are much like the human eye, these varied patches of intensity appear as optical “speckles,” such as spots or blotches on the image that look brighter than other portions of the image. Further, this spot-to-spot intensity difference can vary depending on an observer's (or sensor's) position, which makes the speckles appear to change when the observer or sensor moves. The resulting images with speckle have varied colors with varied brightness in dots, blotches, and so forth.

One conventional way to reduce speckle is to overdrive the VCSEL, and by about 20% for instance. Overdriving refers to increasing the current providing the electrical field that produces the light propagation through the VCSEL. The greater the current, the more variation or range in wavelengths that can be produced by a VCSEL, resulting in reduced speckle. This, however, results in larger and costly power dissipation and results in heating up a camera module adjacent the VCSEL on the same image capture device. The heat impacts the camera performance (i.e., image quality) by degrading or otherwise influencing those camera components such as sensors that are sensitive to temperature, or requiring the use of more expensive thermal resistant materials. Thus, a better solution is desired to reduce speckle noise at lower power dissipation.

Another alternative to reduce speckle is to increase the number of emitters (or VCSELs) on a VCSEL array to reduce speckle noise. The more emitters, the greater the range of wavelengths of the light emitted by an array due to manufacturing tolerances. This structure, however, results in a larger footprint which is more costly (in terms of material and space) and undesirable for small form factors.

Yet another attempt at speckle reduction includes using an optical diffuser above each VCSEL on a light package and with the diffuser placed an optimized height above, and spaced from, a light emitting surface of the VCSEL. This diffuser configuration, however, introduces a performance/size tradeoff forcing the package to be taller to hold the diffuser, which may be undesirable in many small form factors and may increase material and assembly costs as well.

A better solution to provide speckle reduction while maintaining low cost, low power usage, and a small illuminator size (in both height and footprint) is described herein and includes use of an illuminator that eliminates or reduces speckle by using a light source that comprises multiple sets (or arrays) of vertical-cavity surface emitting lasers (VCSELs) and that may be arranged on a single substrate to emit light in multiple wavelengths with a different average (or dominant) wavelength from individual arrays. Particularly, sufficiently different wavelengths will not cleanly combine and subtract from each other but will average out instead, resulting in lower contrast speckle.

In more detail, when a surface is illuminated by a light wave, according to diffraction theory, each point on an illuminated surface acts as a source of secondary spherical waves. The light at any point in the scattered light field is made up of waves which have been scattered from each point on the illuminated surface. If the surface is rough enough (such as facial skin) to create path-length differences exceeding one wavelength, giving rise to phase changes greater than 2π, the amplitude, and hence the intensity, of the resultant light varies randomly. If light of low coherence (i.e., made up of many wavelengths) is used, a speckle pattern will not normally be observed, because the speckle patterns produced by individual wavelengths have different dimensions and will normally average one another out. Thus, speckle contrast reduction is essentially the creation of many independent speckle patterns, so that they average out on the retina, or in this case on the detector's sensor.

Specifically, speckle reduction can be said to be based on averaging S independent speckle configurations within the spatial and temporal resolution of a detector (camera or sensor). It has been proven that, under the most favorable condition, where all the S independent speckle configurations have equal mean intensities, the contrast is reduced by a factor of \sqrt{S}. This is achieved by emitting less coherent light with varying wavelengths.

This reduction in speckle by the averaging out of the speckle patterns can be achieved by wavelength diversity, i.e., use of laser sources which differ in wavelength by a small amount. A speckle pattern depends on the wavelength of the illuminating light. The speckle patterns from two beams with different wavelengths become uncorrelated if the average relative phase-shift created by the surface is ≥2π. Thus, the wavelength difference should be:

δλ≥λ²/2z (1)

where z is the surface profile height variation of the illuminated surface. For example if wavelength λ=0.85 μm and height variation z=0.1 mm, the wavelength difference should be ≥3.6 nm.

On conventional VCSEL arrays, each VCSEL in the array tends to have very close to the same wavelength, less than 1 nm difference. This is due to the close proximity of the emitter elements within the array and the uniform wafer characteristics of the usually epitaxially grown laser structure. Therefore, the individual VCSELs in a conventional 2D VCSEL array form speckle patterns that are nearly identical. These patterns combine to form high contrast speckle where the difference between the dark and light speckle spots can be greater than with a single VCSEL. High contrast speckle results in high levels of noise in the image that can wash out the actual image data (or signal) such that the speckle limits the ability of an imaging system to resolve fine spatial detail on an image. When mere low contrast speckle is present, either the speckle is sufficiently small so that image data (or signal) around the speckle is sufficient to reconstruct the image data (or is so small it is not needed), or the image data (or signal) can be discerned through the relatively dispersed, low-contrast speckle itself.

Here, the multiple VCSEL arrays may each have a different mean or dominant wavelength, and by one form, that is different by at least about 1 nm, from the dominant wavelength of at least one other of the arrays. Thus, by varying laser emission wavelengths of the VCSEL arrays from one array to another array, the arrays produce a resulting image with multiple overlapping speckle patterns which average to result in low-contrast speckle (referred to herein as reduced speckle).

The creation of VCSEL arrays with differing wavelengths can be achieved by using multiple VCSEL arrays that emit multiple wavelengths in at least a couple of different ways without creating significant limitations on the imaging capabilities of the host illumination system. By one form, the VCSEL apertures vary from array to array, where aperture here refers to the diameter or width of a distinct stack of one or more layers forming a VCSEL mesa that differentiate one VCSEL from another adjacent VCSEL. Each aperture size (and in turn each array) will correspond to a different transverse emission mode where a mode indicates the number and size of dominant wavelengths it emits. This results in large wavelength diversity that reduces speckle noise without increasing the Y-footprint or Z-height of the illuminator.

Another way to reduce speckle, or at least achieve more lower contrast speckle, is to use ultrathin metalayer optical elements (or just metalayers) as polarizers on each or individual VCSELs where the metalayers on the VCSELs of one array direct the light into a direction of polarization (a grating direction) that is different than the direction of polarization (or grating direction) of metalayers on VCSELs of another array so that the light from the two arrays is incoherent and produces speckle patterns that average out as explained above. This is performed by having nanoparticles (or posts) on the metalayers elongated in a certain direction (in top view) on one of the arrays and elongated in a different direction (in top view) on at least one other array. This results in polarization diversity that reduces speckle noise without increasing the Y-footprint or Z-height of the illuminator. The metalayer may be referred to interchangeably herein as a metamaterial, metasurface, meta-lens, metamaterial lens layer, metamaterial layer, beam shaper, or any combination of these. Otherwise, both array-based techniques of the VCSEL aperture and metalayer polarizer strategies may be used on the same device.

These speckle reducing implementations result in ultralow speckle contrast, and in turn, can provide higher image resolution and robust outdoor performance since reduced speckle will provide better light contrast detection, with a compact illumination system in terms of footprint and height of the VCSELs and in turn the illuminator, and lower power consumption since overdriving can be avoided. The saved power can be used for other modules of the object detection, other applications, or can simply provide the small-factor device with longer battery power.

As to the second disadvantage of VCSELs labeled (2) above, the conventional VCSEL cannot provide desired intensity peaks on a far-field radiation distribution pattern (referred to as a M-shaped or bat-wing pattern (FIG. 7)) to provide a more uniform light intensity and SNR distribution throughout an image. This target bat-wing far-field radiation distribution is explained in detail by the U.S. patent application Ser. No. 15/793,795 filed Oct. 25, 2017, and published as U.S. Patent Publication No.: 2018/0129866, published on May 10, 2018, and which is incorporated herein in its entirety for all purposes (referred to below as the '795 application). To provide a more uniform light intensity throughout an image, a metalayer, whether or not acting as a polarizer as mentioned above, also may be placed on each or individual VCSELs to direct light to form the desired intensity peaks on the radiation distribution pattern. The metalayer reduces the undesired high light intensity in the center of the radiation pattern and forms intensity peaks nearer the outer edges of the pattern forming the M-shape or batwing shape. The metalayer is structured to make SNR more uniform, and in a relatively small package such as less than 1.5 mm in the Z (height) dimension by one example. This is accomplished by shaping multiple sub-wavelength light scattering nanoparticles or posts on the metalayer. The details for such posts are provided below.

Referring now to FIG. 2, an image processing system 200 may be used for facial or other object recognition according to one or more of the implementations herein. The image processing system 200 has a VCSEL illuminator 202 with multiple arrays of VCSELs as described herein. The illuminator 202 is shown emitting light onto an object 204, such as a face but could be other objects. The light may be emitted in a desired far-field radiation pattern discussed herein as well. A camera 220 may receive the reflected light and may have imaging optics that receive the light emitted from the illuminator 202 and reflected from the object 204. The optics may include a lens 206 and an optical filter 208 such as a color band pass filter. The lens 206 may provide a light reception pattern, while the optical filter 208 may limit the spectral response of the camera. One or more hybrid RGB-IR sensors 210 are provided on the camera for this example but could be for monochromatic light such as IR instead. The sensor 210 may receive the light, as limited by the sensor's numerical aperture, and produce raw image data including RGB extracted data 214 and NIR extracted data 216 that is processed by an image signal processing unit 212. The data then may be used by an object detection unit (or here a face login unit for example) 218.

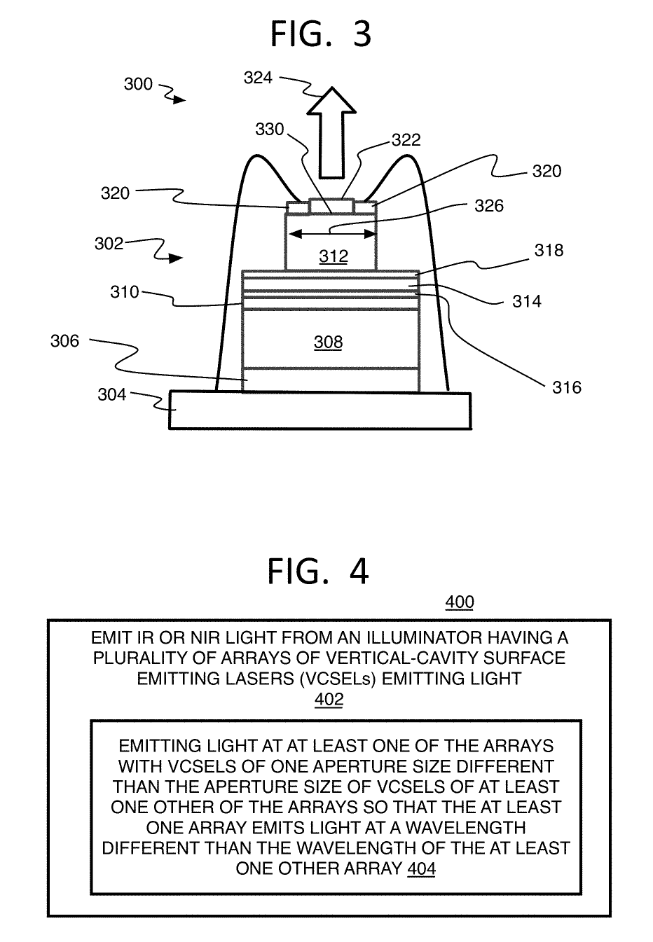

Referring to FIG. 3, a light package or device (or illuminator) 300, such as illuminator 202, is used to emit light according to one or more implementations herein and has a plurality of VCSELs in arrays described herein and where one of the VCSELs 302 is shown here on or in a body or casing 304. The VCSEL 302 is placed on an electrical contact 306 and has a substrate 308, distributed Bragg reflector (DBR) (or mirror) layers 310 and 312, an active region 314 of quantum well and barrier layers between two confinement layers 316 and 318. The upper DBR layer 312 is considered to form the light emitting surface 330 for the VCSEL. A metal contact 320 surrounds a light directing plastic silicon lens or metalayer 322 as explained herein and that emits light 324 from each VCSEL. On an array of VCSELs provided on an illuminator, each VCSEL may have its own lens or metalayer 322 as shown on the single VCSEL on illuminator 300. Here, no diffuser is provided above the VCSEL so that the package 300 can be shorter than such conventional diffuser-using illuminators.

The VCSEL 302 provides a fall-off at the outer wings of a bat-wing (or M-shaped) or other similar far-field radiation distribution pattern. Such an M-shaped pattern or curve 702 is shown on graph 700 (FIG. 7). The VCSEL creates steeper inclined outer ends of the pattern 702 which reduces wasted power consumption that conventionally is used to form the pattern at the edges of an image, while the metalayer forms raised peaks and a central valley between the peaks in the light intensity radiation pattern thereby resulting in a more uniform intensity and SNR pattern across a captured image. Such use of the VCSEL is explained in detail as disclosed by the '795 Application cited above.

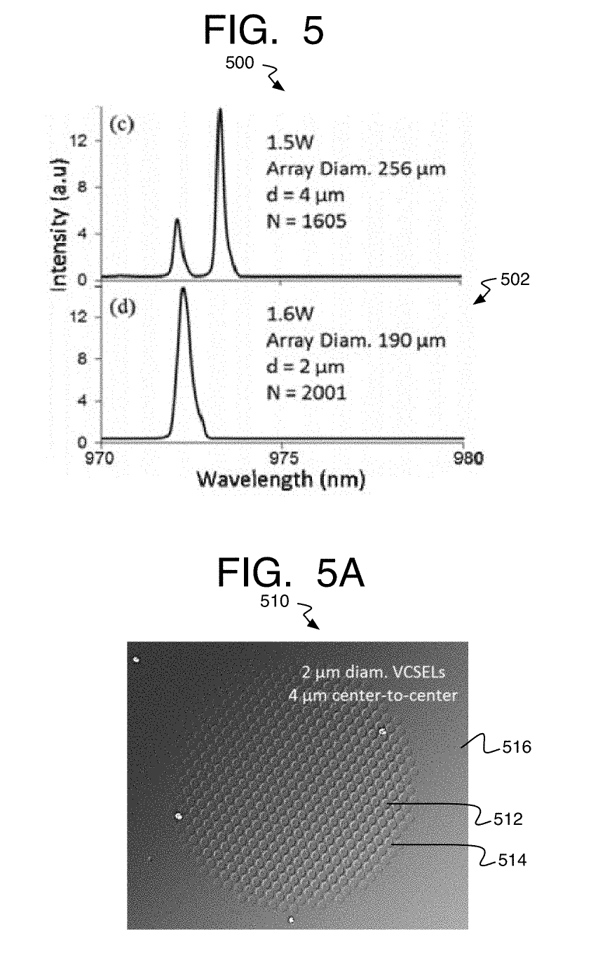

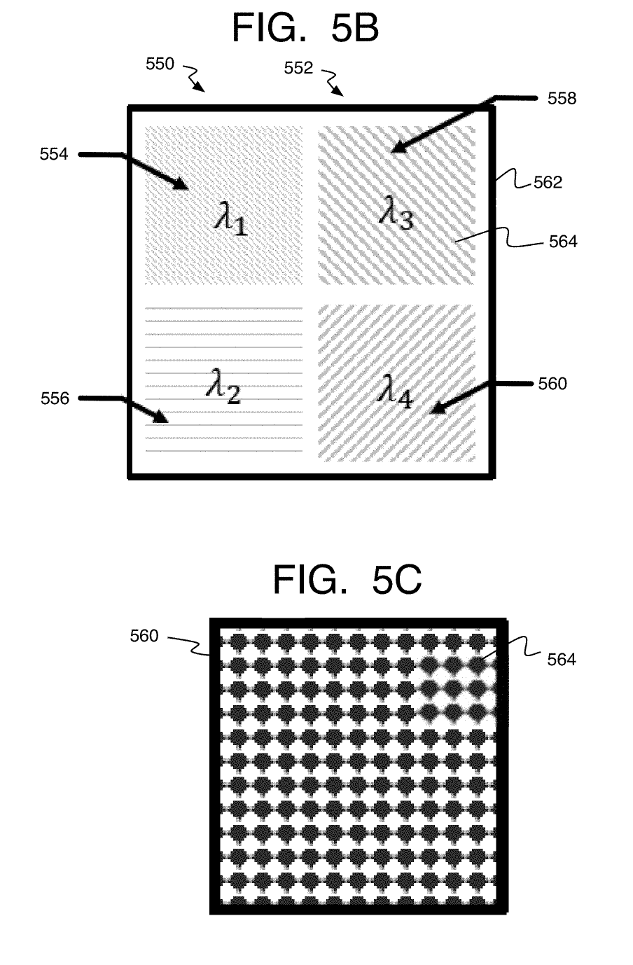

As to the reduction of speckle, multiple VCSELs 302 may be provided in arrays with one array of the VCSELs emitting light in a dominant or mean wavelength different from that of another array of the VCSELs. The wavelength of one array being different refers to a dominant wavelength (which may be a mean, peak, or other representative wavelength) of an array while the array may emit light in a range of wavelengths that could overlap with each other, as long as the difference in dominant wavelength from one array to the other is sufficient to reduce speckle. By one form, one array may have VCSELs with 2 μm apertures 326 to form a single wavelength mode while another array may have VCSELs with larger apertures 326 to form multiple wavelength modes (or multi-modes) as explained below. The aperture is the effective diameter or width of the VCSEL that transmits light and is distinct from VCSEL to VCSEL. This is shown in top view with FIG. 5A below. As for VCSEL 302, the diameter 326 is the aperture at the upper DBR layer 312 and forms a VCSEL mesa (also referred to herein as a VCSEL element or just element or waveguide). In this configuration, more than one VCSEL mesa may share the same substrate 308 or may have a separate substrate mesa it sits upon. When VCSEL mesas share the same substrate 308, it also may share one or more of the layers below the upper DBR layer 312 and above the substrate 308 such as the lower DBR layer 310, active region 314, and confinement layers 316 and 318. By one approach, at a minimum, the VCSEL mesa or element provides a distinct diameter or width 326 relative to adjacent such elements while having the light emitting surface of the VCSEL as long as the element is light transmitting regardless of the light transmitting material forming the element layer or layers. Thus, it may not be always formed mainly of a DBR layer as here. This configuration of the VCSEL may be used as described in the implementations below.

Also as mentioned, the metalayers 322 on VCSELS of one array may be arranged to polarize light in a different direction than the light is polarized by metalayers of VCSELs on another array so that the speckle patterns from the two arrays average out. This is accomplished by shaping posts on the metalayers in different ways for each array as described below.

Referring to FIG. 4, an example process 400 for emitting light to capture images is arranged in accordance with at least some implementations of the present disclosure, and specifically, for example, while using a VCSEL illuminator for reducing speckle. Process 400 may include one or more operations 402-404 numbered evenly as illustrated in FIG. 4. Process 400 will be described herein in reference to systems or illuminators 200, 300, or 1500 of FIG. 2-3 or 15 respectively, and where relevant.

The process 400 may include “emit IR or NIR light from an illuminator having a plurality of arrays of vertical-cavity surface emitting lasers (VCSELs) emitting light” 402. By one form, an illuminator comprising at least one light source has a stack of layers comprising a layer with a light emitting surface. The light source is a monochromatic light source, and in one form, is an infra-red (IR) or near-infra-red (NIR) illuminator that comprises a vertical-cavity surface emitting laser (VCSEL).

Process 400 also may include “emit light at at least one of the arrays with VCSELs of one or more aperture sizes different than the aperture size or sizes of VCSELs of at least one other of the arrays so that the at least one array emits light at a dominant wavelength different than the dominant wavelength of the at least one other array” 404. As described herein, this is accomplished by using different VCSEL aperture sizes on one array of the VCSELs compared to another array of the VCSELs. By one form, apertures on the arrays may vary from array to array on sizes from about 1 μm to 10 μm, and in one example, one array has apertures of about 2 μm while the aperture of other arrays may be larger such as 3 or 4 μm (other sizes could be fractions of these such as 2.5 μm, etc.). By one form, four arrays are used but may be as many as six arrays, where each array may have VCSELs with a different size aperture. By one example, for four arrays, each pair of diagonally positioned arrays have the same aperture size and that is different than the other two diagonally positioned arrays. By yet another example, one array may intentionally include a range of aperture sizes to form a desired dominant wavelength that is different than a dominant wavelength of another array. A number of these variations are described below with FIG. 5B. Other variations are contemplated.

By yet another example, each or individual polarizers may be provided on the VCSELs in the form of metalayers with posts shaped to polarize the light in a certain direction. By one form, the posts are elongated in top view in one direction, say along a y-axis, for one of the arrays so that the polarized light oscillates in a linear or other pattern in the direction of the long face of the posts, while the posts are elongated in the x-direction on another of the arrays. The resulting different polarization of the light from the two arrays will generate light in waves that average out rather than add or subtract to cause high contrast speckle. This assumes the direction of the applied electric field, and in turn the direction of the magnetic field, remains the same from array to array in order to generate the different polarization directions from array to array by changing the shape of the posts. This technique may be combined with the varying of VCSEL apertures on the same illuminator to better ensure reduction of high contrast speckle. By one form, the differences in apertures corresponds to the differences in polarizers so that arrays with the same aperture have the same polarizer, and those arrays with different apertures also have different polarizers. Otherwise, the opposite could be used where arrays with the same apertures have different polarizers, and arrays with different apertures have the same polarizers, or any other combination may be used that tends to average out speckle patterns.

Referring now to FIG. 5, single transverse mode laser diode arrays have been desirable for creating high power laser diode sources capable of achieving both high beam quality and spectral control. The transverse mode is the number of separate dominant light wavelengths (in nm for example) emitted by an array of the VCSELs. Here, VCSELs can achieve single mode output using elements with small apertures (e.g., about 2 μm or less) measured at the distinct upper element (such as the upper DBR layer) of the VCSEL as described above on VCSEL 302 (FIG. 3). As an example, two graphs 502 and 504 show lasing spectra of a single aperture device and the various element size arrays, where N is the number of distinct VCSEL elements in the array, W is power in watts, and d is the emitting VCSEL diameter (also referred to as the VCSEL's aperture) of each element. The number of transverse modes (shown by each peak) decreases with element VCSEL diameter d, with the d=2 μm element emitting only a single transverse mode on graph 500. However, if the element is relatively wide at the diameter/aperture of the VCSEL up to 4 μm, then the element can support multiple transverse optical modes, and the laser is known as “multi-mode” as shown on graph 502. A single transverse mode VCSEL array based on a lithographic fabrication technique enables good packing density and laser element uniformity. Such technique with arrays of such VCSELs, tested with various alternative different aperture sizes, and that enables emission of varying wavelengths for individual VCSELs is disclosed by J. Leshin, et al., “Lithographic VCSEL Array Multimode and Single Mode Sources for Sensing and 3D Imaging,” Proc. of SPIE Vol. 9854, 98540Y, 2016. doi: 10.1117/12.2222911.

Lithographic VCSELs have proven to be superior to oxide-aperture VCSELs (currently in production by most VCSEL suppliers) in numerous properties, most notably for small sizes. Such benefits include high power conversion efficiency and low thermal resistance, increased reliability, as well as stable single transverse mode output. Achievements in improved beam quality and spectral control allow these lithographic arrays to avoid the ‘donut’ mode pattern seen in arrays made with larger VCSEL elements.

Referring to FIG. 5A, an example illuminator 510 has a VCSEL array 512 formed of individual lithographic VCSELs 514 visible at their elements on a substrate 516 and formed by using the processes mentioned herein. The VCSEL elements may be 2 μm diameter single transverse mode VCSELs 514 spaced 4 μm center-to-center. The VCSEL elements have high uniformity in their size and operation.

Referring to FIGS. 5B-5C, an illuminator 550 has a multiple VCSEL array pattern 552 to reduce the speckle. The illuminator 550 may have a substrate 562 with two or more VCSEL arrays, and here four such arrays 554, 556, 558, and 560, each having an array of VCSELs 564. By one form, each array is the same size and shape with the same number of VCSELs, and by one example, in the same row and column arrangement, here forming squares or rectangles. A close-up of VCSEL array 560 is provided at FIG. 5C with individual VCSELs 564, where each VCSEL 564 is visible due to its distinct element (or waveguide or VCSEL mesa). Each VCSEL array 554, 556, 558, and 560, by one option, has a different dominant wavelength λ₁, λ₂ λ₃, or λ₄ respectively as shown. According to the present example, each dominant wavelength λ₁, λ₂ λ₃, or λ₄ is at least about 1 nm different than any of the other dominant wavelengths of the other arrays. By one example, the dominant emission wavelengths of each array may be within about 4 nm of a wavelength of 850 nm.

In this example, only four arrays are shown, but any number of multiple arrays such as two to six arrays may be used. By one form, a VCSEL array pattern of 3×2 arrays may be used where each array has VCSELs with a different aperture size than the size of the apertures of VCSELs of a different array, and in turn, different wavelength. By other forms, 3×3 or even 3×4 arrays could be used. As mentioned, the speckle may be reduced by 1/\sqrt{S}where S is the number of arrays (or number of speckle patterns). Despite the number of arrays here up to six, this still creates a much smaller footprint than would the total number of VCSELs needed to reduce speckle by providing a sufficient variation in speckle patterns simply by relying on the manufacturing tolerances of the VCSELs.

By other alternatives, a diagonal pattern could be used where pairs of diagonal arrays have the same dominant wavelength such that wavelengths λ₁ and λ₄ are the same, and wavelengths λ₂ and λ₃ are the same. By other forms, horizontal or vertical pairs of arrays have the same wavelength. By one form, apertures on the arrays may vary from array to array on sizes from about 1 μm to 10 μm, and in one example, one array has apertures of about 2 μm while the aperture of other arrays may be larger such as about or exactly 3 or 4 μm (other sizes could be fractions of these such as about 2.5, etc.). By one form, the largest aperture is 4 μm for any of the arrays, and by one example, only apertures of about or exactly 2, 3, and 4 μm are used such as two diagonal arrays λ₁ and λ₄ having VCSELs with 2 μm apertures while λ₂ has 3 μm apertures and λ₃ has 4 μm apertures. By yet other alternative examples, one array may intentionally have VCSELs with a range of aperture sizes while another array may have VCSELs with a different range of aperture sizes where each range has a different average dominant wavelength where the difference is sufficient to reduce speckle. Many other variations can be used.

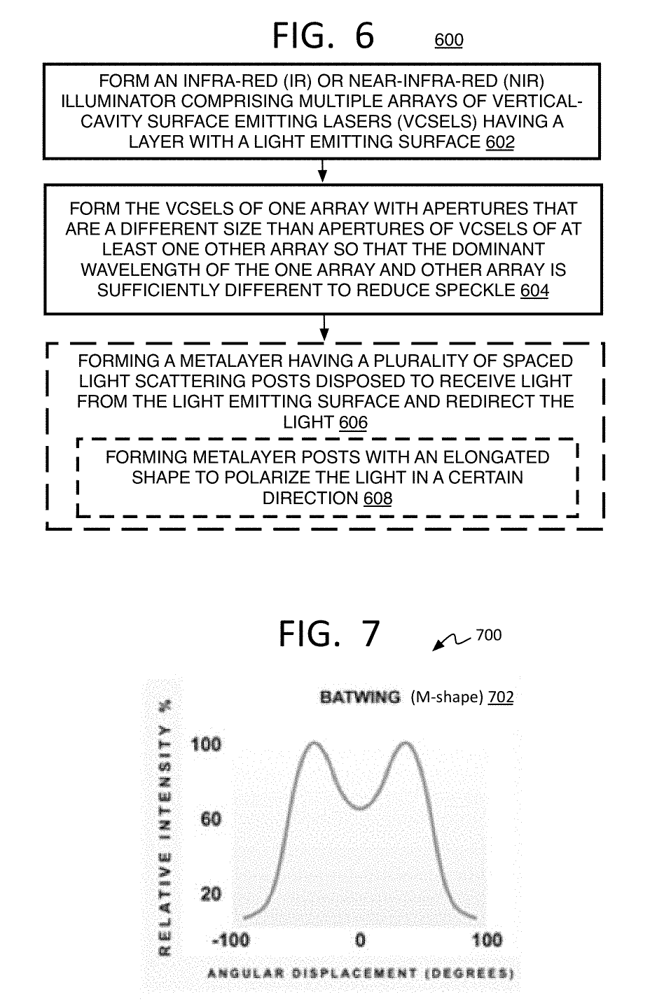

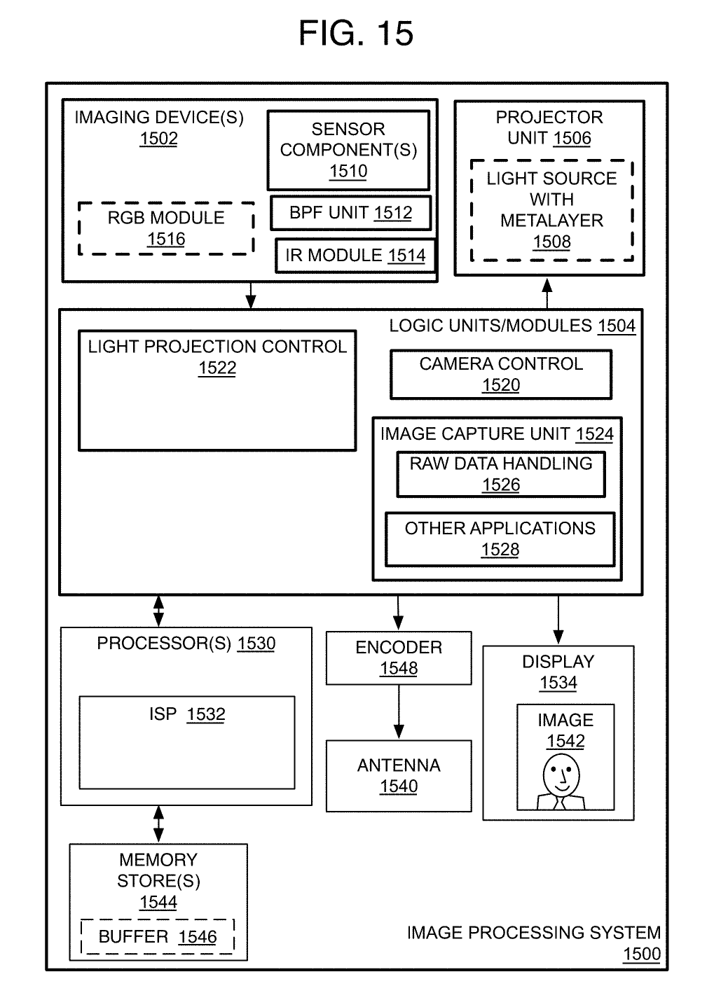

Referring to FIG. 6, an example process 600 for forming a light emitting device is arranged in accordance with at least some implementations of the present disclosure. Process 600 may include one or more operations 602-608 numbered evenly. Process 600 may form at least part of illuminators as shown at FIGS. 2-3. Furthermore, process 600 may be described herein in reference to system 1500 of FIG. 15, and where relevant.

Process 600 may include “forming an infra-red (IR) or near-infra-red (NIR) illuminator comprising multiple arrays of vertical-cavity surface emitting lasers (VCSELs) having a layer with a light emitting surface” 602. As mentioned above, lithographic or other such techniques may be used to form arrays of the VCSELs such as those structured similarly to VCSEL 302 (FIG. 3). Alternative manufacturing techniques are mentioned below.

Process 600 also may include “forming the VCSELs of one array with apertures that are a different size than apertures of VCSELs of at least one other array so that the dominant wavelength of the one array and other array is sufficiently different to reduce speckle.” 604. Also, as mentioned, the apertures of the VCSELs may be formed so that the dominant wavelength is different from array to array, and by one example, is at least 1 nm different in dominant wavelength. It will be understood that the VCSELs of one array being formed with the same or one aperture includes manufacturing tolerances for that aperture measurement or may include an intentional range of aperture sizes for a single array that form a desired dominant wavelength (which may or may not be the average wavelength or a peak wavelength) for that array. The sizes of the apertures for different arrays are mentioned above.

Optionally, the process 600 also may include “forming a metalayer having a plurality of spaced light scattering posts disposed to receive light from the light emitting surface and redirect the light” 606. This operation may include “forming metalayer posts with an elongated shape to polarize the light in a certain direction” 608. Thus, the metalayers posts on VCSELs of one array may extend (be elongated in) in one direction (in top view), while the metalayer posts of VCSELs on another array may extend (be elongated in) in a different direction (in top view) than on the other array. When two arrays have VCSELs with metalayers that have posts elongated in different directions, the light will be polarized differently from array to array. The waves of the light emitted in different polarization will average out rather than add or subtract resulting in reduced speckle. The details are provided below.

Referring to FIGS. 8-14, the polarizer or polarizing metalayer is described in more detail. First though, with regard to control of the illumination pattern, the metalayer may be placed on the emitting surface of the VCSEL to generate desired light intensity peaks at the outer image emission angles (the angles that will form the outer edges and corners of the image) which is a smaller angle than the total emission angle. This is performed while reducing the light intensity at the center (or optical axis) of the illuminator, and in turn, the resulting images. This is achieved by establishing a far-field batwing (or M-shaped) light intensity or radiation distribution pattern 702 (FIG. 7) where the intensity peaks form the upper points on the M-shaped pattern and light intensity is reduced between the peaks to form the M-shape. The metalayer may be arranged to form the desired illumination pattern for a specific application. By using a VCSEL with a metalayer as the illuminator, the illumination pattern of the VCSEL may be controlled or tuned for the application so that less energy is wasted at the outer wings of the M-shaped (or batwing shaped) radiation pattern 702.

To generate light in the desired radiation pattern, the metalayer is arranged as follows. If an array of the posts, which act as subwavelength resonators, have negligible thickness and are added to a light emitting interface or surface, the reflection and transmission coefficients may be changed because the boundary conditions are modified by the resonant excitation of the effective current within the metasurface. For example, the reflection and transmission waves may carry a phase change that may vary from −π to π, depending on the wavelength of the incident wave relative to the surface electric/magnetic resonance and other parameters of the metalayer as explained below. When the phase change is uniform along the interface (without posts), the directions of reflection and refraction may be unaltered. In contrast, metalayer posts create spatial phase variation caused by having the posts separated by another media such as the air between the posts for example with subwavelength resolution (or post widths) to effectively control the direction of wave propagation and the shape of the resulting wavefront. Such control may be useful for beam focusing/steering applications, or the like. Many other details for controlling the far-field radiation pattern are disclosed by the '795 patent application cited above, and which are incorporated herein.

Referring specifically to FIG. 8, an example metalayer (or metasurface) 800 may have an array 802 of the posts 804 on a base or substrate 806 that is flat or otherwise generally planar with a thickness of th_{b} of about one-half the dominant wavelength. The base 806 may be placed on an upper surface 810 of a top or upper layer 808 of a light source 812 such as a VCSEL. The top layer 808 of the light source may be a DBR for example. The size of each post 804 including the height H (or t_{g}), width W (or s), and length L as well as the spacing ‘a’ between posts and arrangement of the posts relative to each other all may be selected to steer the light to form the desired far-field light intensity radiation pattern, such as the batwing or M-shaped pattern 702 (FIG. 7), as well as to provide a certain polarization direction. By one form W is about four to ten times smaller than the generated wavelength of the light received from the light source, and H and L are at most about half the wavelength of the light. By one form, W is 1/10 of the wavelength while H and L are about half the wavelength. Other variations are mentioned below.

The posts (also referred to by many names including optical antennas, meta-atoms, nanostructures, nanoparticles, nanoscatterers, subwavelength scatterers, and resonators) receive light from the light emitting surface and steers the output light to form the desired radiation pattern. The term “post” here simply refers to the post extending away from a substrate surface to form a distinct structure from the substrate and does not necessarily mean the height of the post is greater than a width or diameter of the post, nor that the post must extend vertically relative to the earth.

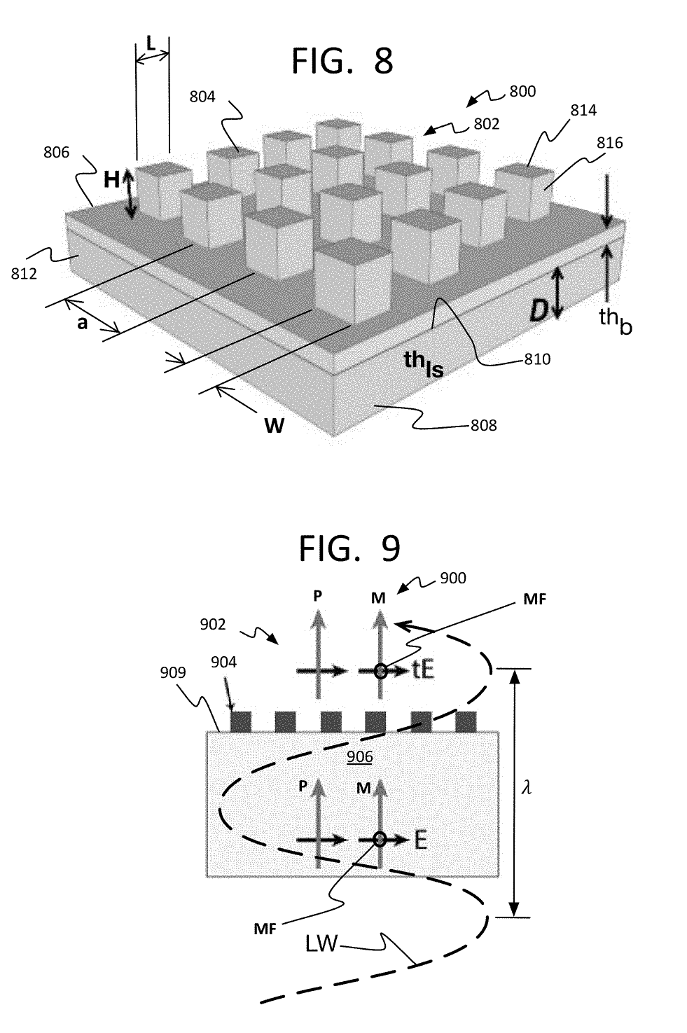

Referring to FIG. 9, a metalayer 900 has an array 902 of posts 904 on a substrate 906. Light is propagated from a light source, such as the VCSEL, forming a light wave LW shown in dashed line, where it oscillates left and right while it flows in the propagation direction P, and has a wavelength λ. The wave is forced to propagate in the desired direction P by running an electric current in a transverse direction E to the desired direction P of propagation. For dielectric nanodisk layers, incident radiation or light brings both electric and magnetic responses of comparable strengths. The coupling of incoming light to the electric field's circular displacement current E results in a strong magnetic dipole resonance in direction M and resulting in a transverse magnetic field in direction MF (in and out of the paper and normal to the electric field direction E and propagation direction P). The magnetic resonance and light coupling occurs when the wavelength of the light traveling through the posts is a multiple of the lateral dimension of the posts—that is, when the size of the post is:

post width W≈λ/n (2)

where n is the refractive index of the post material, and λ is the light's wavelength.

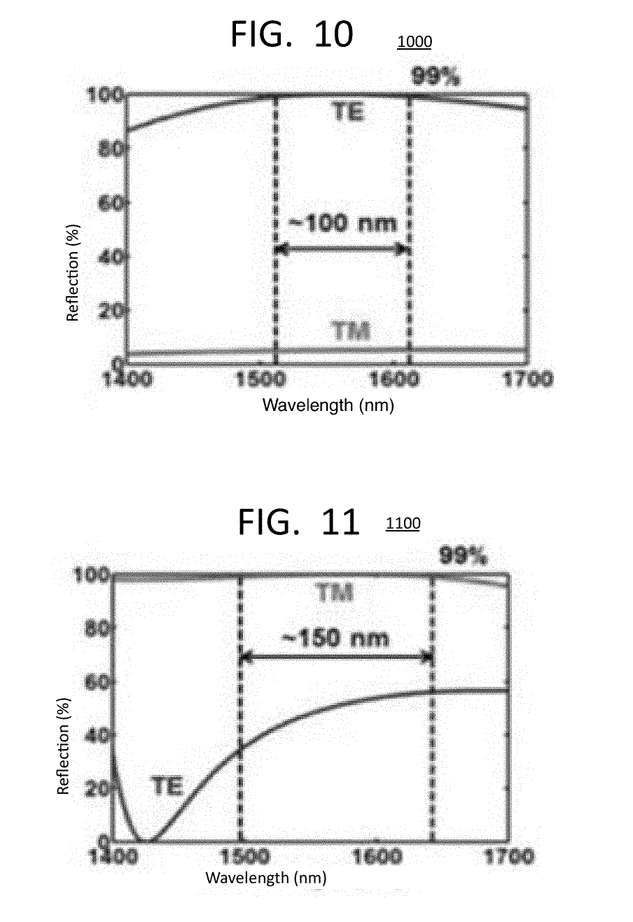

Referring to FIGS. 10-11, and with regard to the use of the metalayers as polarizers, it has been found that there is a very large reflectivity difference between TE (Transverse Electric) and TM (Transverse Magnetic) polarizations as shown on graphs 1000 and 1100. The polarizer in this case is a simple grid of dielectric bars (or posts) aligned with TE or TM waves of the incident light. Thus, the elongated face of the posts will direct the polarization direction, and the orientation of the posts determine the polarization selectivity. On graph 1000, the optimized TE polarizer has a very high reflectivity for E-field along the y-direction (parallel to the E-field) where graph 1000 shows that 99% reflectivity can be maintained for about 100 nm, but significantly lower along the x-direction. On the other hand, the simulated reflectivity spectrum for TM polarizer shown on graph 1100 shows that the optimized TM polarizer has a very high reflectivity for E-field along the x-direction (transverse to the E-field) where graph 1100 shows that 99% reflectivity can be maintained for about 150 nm, but significantly lower along the y-direction. This enables polarization selection by integrating such metasurfaces on the VCSEL.

By elongating a metalayer post or bar in top view in the y-direction parallel to the electric field E and transverse to the magnetic field MF, the polarization will extend in one direction, such as parallel to the y-axis for one possible example. However, when the posts are elongated along the x-axis transverse to the E-field but parallel to the magnetic field MF, the polarization may be directed in a different direction than in the y-axis direction, such as parallel to the x-axis direction. This assumes the applied direction of the E-field and, in turn, the applied direction of the magnetic field MF does not change from array to array. This may form linear polarization in the different directions, but the generated polarization could be of different shapes. By forming metalayers with posts elongated in the same direction on the metalayer, and then having such metalayers on VCSELs in the same array of VCSELs, but where metalayer posts of VCSELs of a different array generally extend in a different direction, each array of VCSELs on an illuminator can be arranged to emit light with a different polarization, thereby reducing speckle.

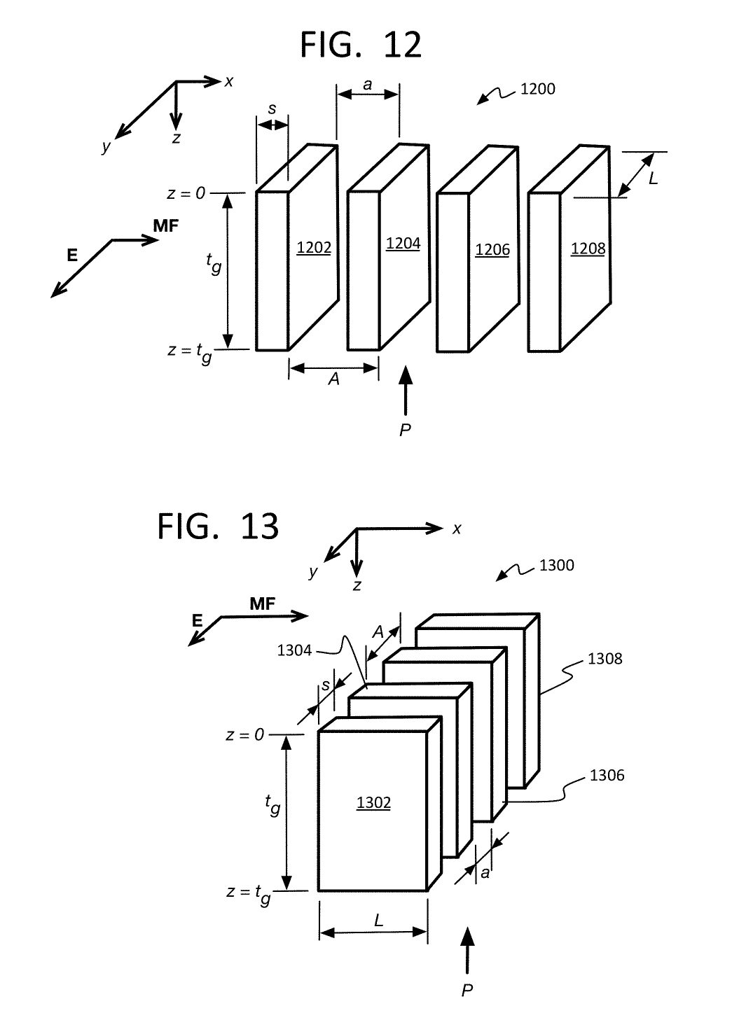

Referring to FIG. 12, an example metasurface 1200 has polarizing posts 1202, 1204, 1206, and 1208 all elongated in the same direction along or parallel to the y-axis, and where P is the direction of light wave propagation, E is the direction of the electric field, and MF is the direction of the magnetic field normal to the electric field, and where both E and MF are transverse to the direction of propagation P. The dimensions of each post include a height t_{g}, a width s transverse to the y-axis and E direction, and elongated length L parallel to the y-axis and E-direction, and transverse to the magnetic field direction MF.

For infrared light with wavelength of 800 nm, elongated length or direction L is approximately 400 nm or λ/2. A phase aspect ratio of the posts (t_{g}:s) is at about or less than 5:1. Thus, the thickness (or height) of dielectric bars t_{g}≈/2 while the width s may be about λ/10. The space between adjacent posts a is about λ/2 and here about 400 nm, with edge to edge spacing A being about 480 nm in this example. By the example provided in graph 1100 for a wavelength of about 850 nm, the value of s may be about 100-150 nm. Thus, in top view, the polarizing ratio of elongated length L to widths should be about 4.25:1 to 5.7:1 (or generally 4:1 to 6:1) by one example for 850 nm wavelength. For about an 800 nm wavelength, the polarizing ratio should be from about 2.7:1 to 4:1 (or generally 3:1 to 4:1), or generalizing for both wavelengths at about 3:1 to 6:1.

Referring to FIG. 13, a second post configuration is shown on a metasurface 1300 with posts 1302, 1304, 1306, and 1308, all elongated in the same direction along or parallel to the x-axis. The dimensions of the posts for metasurface 1300 are the same as that of metasurface 1200 except the posts are elongated in a different direction. It should be noted that the directions of the electric field E and magnetic field MF remain the same. This generates light in a polarization direction that is different than the polarization direction of metasurface 1200 because the shape of the posts are different, and particularly since the posts are elongated (in top view for example) in a different direction relative to the same electric and magnetic field directions used on both metasurfaces (and in turn arrays). By one form, this may generate linear polarization that is along the x-axis, but is at least perpendicular or transverse to the polarization direction of the metasurface 1200. By one form, the directions of the two polarizations are different so that they are exactly or substantially perpendicular to each other when linear, or may have long axes of ellipses or other shapes defined about a long axis that are different in this way. Otherwise, the direction of polarization should be sufficiently different than that produced by other metasurfaces so that the light waves average out to reduce speckle. Thus, metasurfaces 1200 may be placed on VCSELs in one VCSEL array while metasurfaces 1300 may be placed on VCSELs of another array so that one array emits light in one polarization direction while the other array emits light in a different polarization direction. The metasurface polarizers are integrated on different VCSEL arrays to produce polarization diversity, which reduces speckle by \sqrt{S}=1.414, where S=2 arrays for example.

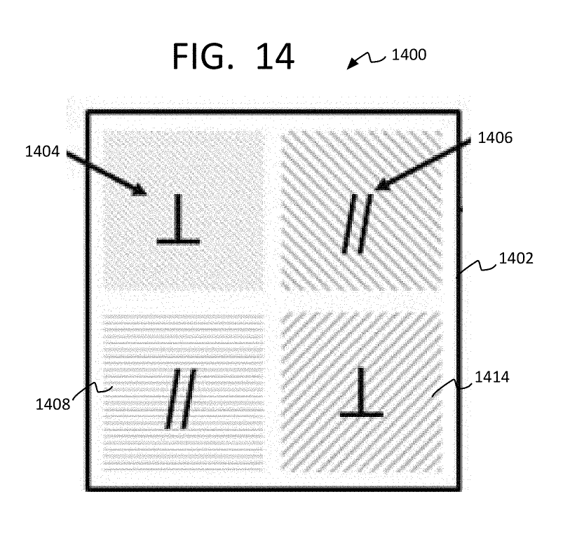

Referring to FIG. 14, an example illuminator 1400 is shown with a substrate 1402 and four VCSEL arrays 1404, 1406, 1408, and 1410 on the substrate 1402. In this example, a pair of diagonally positioned arrays 1404 and 1414 have meta surfaces on VCSELs with posts that extend in the same or similar direction and perpendicular to the electric field E direction (as on metasurface 1300), while the posts on the VCSELs of the other diagonal pair of arrays 1406 and 1408 extend in a direction parallel or about parallel to the electric field E as in metasurface 1200. Thus, the waves, and in turn the speckle patterns, will average out instead of adding or subtracting from each other, thereby reducing speckle. Many other variations are contemplated as long as least two arrays have different polarization directions. Thus, a check pattern may be continued as arrays are added where diagonally disposed arrays have the same polarization. Otherwise, such differences could be arranged by row or column instead rather than diagonally.

To combine the advantages of both the polarization and VCSEL aperture size techniques here, the metasurfaces may be arranged so that the polarization of arrays are the same when the VCSEL aperture sizes of the arrays are the same. Otherwise, the opposite could be used where arrays with the same VCSEL aperture size have different metalayer polarizations. By yet another alternative, both could be combined for example so that one pair of arrays has the polarization and aperture size change from array to array, but another pair of arrays has either the aperture or polarization stay the same while the other parameter changes.

### Fabrication of “Metasurface” Polarizers

To make a metasurface polarizer, one starts with a flat VCSEL surface, and decorates the surface with carefully-designed nanoparticles or posts. These alter the phase of light as it passes through or reflects, creating a new wavefront. Achieving full control over the phase of light requires precise, high-aspect-ratio phase-controlling (about 5:1 or less height to width) nanostructures, which in turn require the use of nanofabrication methods.

In order to construct the VCSEL array with the metalayer, a method of forming the VCSEL array may comprise each VCSEL element in the array having its own metalayer built above or layered onto the VCSEL as with VCSEL 302 to produce the desired polarization direction as well as the M-shaped or batwing far-field radiation pattern (FIG. 7) or other desired radiation patterns depending on the applications. The VCSEL light wavelength λ used to dimension the metalayer on an individual VCSEL may be the specific wavelength of the particular VCSEL the metalayer is on, but otherwise may be some combination value such as the median, average (or dominant), or other value of wavelength related to the array of VCSELs.

Thus, such a process includes forming a metalayer on each or individual VCSELs on one or more arrays of VCSELs. By this approach, this operation also comprises forming the metalayer with a base portion, and the posts extending from the base portion. The base portion is disposed adjacent the VCSEL to receive the light emitted from the VCSEL. The posts are sized, shaped, and spaced in both direction and distance to impart a polarization of the light waves and a phase on the wavefront as a function of position on the VCSEL surface, thus producing a desired far-field radiation pattern.

This operation also may include arranging the VCSEL and metalayer to cooperatively reduce speckle. The details are explained above but it is sufficient to mention here that this includes forming elongated posts (in top view) that extend in the same direction on the metalayers on the VCSELs of a first array of VCSELs so that the polarizing effect of the posts will form a polarizer in a certain direction on the first VCSEL array. The direction of posts on metalayers of VCSELs on another array can be formed to extend in a different direction than on the first array thereby forming polarization in a different direction for this second or other array, as long as the direction of the applied electric field, and in turn the direction of the applied magnetic field, remains the same from array to array.

Otherwise, planar metamaterials with subwavelength thickness, or metalayers, with a single-layer or few-layer stacks of generally planar structures, may be fabricated as follows. To form the metalayer on the VCSEL (or LED or other stacked layer light source), a flat wafer of the desired material of the metalayer may be formed by chemical vapor deposition, doping, ion implantation, and/or etching. This provides a flat, planar surface to build the posts on. The posts are then formed on the flat surface of the wafer, and may be formed using nanofabrication methods of many different types of lithography such as optical, electron-beam, nanoimprint, multiphoton, x-ray, stencil, charged or neutral particle, and/or scanning probe lithography, as well as molecular self-assembly, laser printing, nanoprinting, and proton beam writing. The fabricated metalayer may be formed on the top layer of the light source, such as the aperture-defining DBR layer of the VCSEL, or may be formed separately and placed onto the light source thereafter.

### Material of Metalayer

The initial metalayers were formed of arrays of metallic posts, whose Ohmic losses are significantly large and strongly affect the converting efficiency, especially in near-infrared and visible wavelength range. All-dielectric (or completely substantially dielectric) metalayers have been considered to avoid Ohmic losses. Owing to their low losses in the visible spectral range, all-dielectric metalayers allow for the realization of practically absorption-less functional devices for wavefront manipulation. In that case, in order to use desirable high refractive index dielectric materials as the metalayer, the diameter of the posts should be subwavelength in size (according to the condition D≈λ/n described above) to control the emitted phase and propagation directions.

To achieve these parameters by one example, the metalayer may be formed of TiOₓ where x is between about 1 and about 2, and by another form, 1<x<2. It has been found that the use of TiOₓ at least with x<2 provides a transparent material that enables a larger refractive index and better scattering efficiency (minimizes optical loss) of the lighting device with the metalayer. The Titanium Oxide may be lightly doped with nitrogen or sulfur. By using Titanium Oxide, optical efficiencies may reach greater than about 90%.

By other examples, the metalayer may be formed of silicon, amorphous silicon (a-Si), Silicon Nitride, Titanium Oxide, or Gallium Phosphide. By other approaches, silicon-germanium with Germanium may be used with a content less than about 20%. The addition of Ge in silicon also results in better scattering efficiency and better transmission efficiency for the metasurface compared to conventional silicon. Otherwise, the metalayer may be formed of SiO₂ or GaP.

In addition, any one or more of the operations represented by the processes or explanations with FIGS. 2 and 4 may be undertaken in response to instructions provided by one or more computer program products. Such program products may include signal bearing media providing instructions that, when executed by, for example, a processor, may provide the functionality described herein. The computer program products may be provided in any form of one or more machine-readable media. Thus, for example, a processor including one or more processor core(s) may undertake one or more of the operations of the example processes herein in response to program code and/or instructions or instruction sets conveyed to the processor by one or more computer or machine-readable media. In general, a machine-readable medium may convey software in the form of program code and/or instructions or instruction sets that may cause any of the devices and/or systems to perform as described herein. The machine or computer readable media may be a non-transitory article or medium, such as a non-transitory computer readable medium, and may be used with any of the examples mentioned above or other examples except that it does not include a transitory signal per se. It does include those elements other than a signal per se that may hold data temporarily in a “transitory” fashion such as RAM and so forth.

As used in any implementation described herein, the term “module” refers to any combination of software logic and/or firmware logic configured to provide the functionality described herein. The software may be embodied as a software package, code and/or instruction set, and/or firmware that stores instructions executed by programmable circuitry. The modules may, collectively or individually, be embodied for implementation as part of a larger system, for example, an integrated circuit (IC), system on-chip (SoC), and so forth.

As used in any implementation described herein except where specifically described above, the term “logic unit” refers to any combination of firmware logic and/or hardware logic configured to provide the functionality described herein. The “hardware”, as used in any implementation described herein, may include, for example, singly or in any combination, hardwired circuitry, programmable circuitry, state machine circuitry, and/or firmware that stores instructions executed by programmable circuitry. The logic units may, collectively or individually, be embodied as circuitry that forms part of a larger system, for example, an integrated circuit (IC), system on-chip (SoC), and so forth. For example, a logic unit may be embodied in logic circuitry for the implementation firmware or hardware of the systems discussed herein. Further, one of ordinary skill in the art will appreciate that operations performed by hardware and/or firmware may also utilize a portion of software to implement the functionality of the logic unit.

As used in any implementation described herein, the term “engine” and/or “component” may refer to a module or to a logic unit, as these terms are described above. Accordingly, the term “engine” and/or “component” may refer to any combination of software logic, firmware logic, and/or hardware logic configured to provide the functionality described herein. For example, one of ordinary skill in the art will appreciate that operations performed by hardware and/or firmware may alternatively be implemented via a software module, which may be embodied as a software package, code and/or instruction set, and also appreciate that a logic unit may also utilize a portion of software to implement its functionality.

Referring to FIG. 15, an example image processing system 1500 is arranged in accordance with at least some implementations of the present disclosure. In various implementations, the example image processing system 1500 may have an imaging device 1502 to form or receive captured image data, and a projector unit 1506 to emit light to be reflected from objects and captured by the imaging device 1502. This can be implemented in various ways. Thus, in one form, the image processing system 1500 may be a digital camera or other image capture device (such as a dedicated camera), and imaging device 1502, in this case, may be the camera hardware and camera sensor software, module, or component 1510, while the projector unit 1506 is the projector hardware including a light source optionally with a metalayer 1508 as described above, and may have projector software, modules or components as well. In other examples, image processing device 1500 may be a multi-purpose electronic device, such as on a smartphone or laptop for example, and may have an imaging device 1502, that includes or may be a camera, and the projector unit 1506. In either case, logic modules 1504 may communicate remotely with, or otherwise may be communicatively coupled to, the imaging device 1502 and projector unit 1506 for further processing of the image data.

Also in either case, such technology may include a camera such as a digital camera system, a dedicated camera device, or an imaging phone, whether a still picture or video camera or some combination of both. This may include a light projection and camera system such as a face detection, iris detection, or detection of other parts on a person to authorize an action or access for that person. Such a system may be provided on a multi-purpose computing device for access to that device, files on that device, or access to other objects, or could be part of a dedicated access authorization system such as a door or safe lock. Other forms for the image processing device 1500 may include a camera sensor-type imaging device or the like (for example, a webcam or webcam sensor or other complementary metal-oxide-semiconductor-type image sensor (CMOS)), with or without the use of a (RGB) depth camera and/or microphone-array to locate who is speaking. The camera sensor may also support other types of electronic shutters, such as global shutter in addition to, or instead of, rolling shutter, and many other shutter types. In other examples, an RGB-Depth camera may be used in addition to or in the alternative to a camera sensor. This may include an RGB-IR stereo camera or single camera.

In one form, imaging device 1502 may include camera hardware and optics including one or more sensors as well as auto-focus, zoom, aperture, ND-filter, auto-exposure, flash (if not provided by projector unit 1506), and actuator controls. These controls may be part of the sensor module or component 1510 for operating the sensor. The sensor component 1510 may be part of the imaging device 1502, or may be part of the logical modules 1504 or both. Such sensor component can be used to generate images for a viewfinder and take still pictures or video. The sensor component 1510 may be arranged to sense IR light, RGB light, or both. A bandpass filter (BPF) unit 1512 may provide filters for IR light, RGB light (such as with a Bayer color filter), or both as well. The imaging device 1502 also may have a lens, an analog amplifier, an A/D converter, an IR module 1514, optionally an RGB module 1516, and other components to convert incident light into a digital signal, the like, and/or combinations thereof, and provide statistical signals and data desired for analysis of an IR image for example (which may or may not include a computed SNR or the signals for another application to compute the SNR). The digital signal also may be referred to as the raw image data herein.

The projector unit 1506 may have those components necessary to operate the light source and metalayer, whether the light source is only an IR or NIR VCSEL, or additionally includes other type of light source to emit IR or another type of light. Thus, the projector unit 1506 may include circuitry to control the power fed to the light source 1508 as well as one or more clock circuits to indicate when to turn the light source on and off. The light source may include one or more arrays of VCSELs by the above examples. The projection module 1506 also may include other light sources, such as for the camera flash, or to provide additional types of light than IR.

In the illustrated example, the logic modules 1504 may include a camera control unit 1520 that manages the various general operations of the imaging device 1502 such as turning the camera on and off and transmits data from the imaging device, a light projection control 1522 that controls the power and lighting circuits of the projector unit 1506, an image capture unit 1524 that has a raw data handling unit 1526 that performs pre-processing on received image data, and then other image processing applications 1528 that process the image data for various purposes such as object detection including face or iris detection, eye tracking, image warping or augmentation, depth detection operations, and so forth. The applications 1528 also may include applications that compute and/or use the SNRs to analyze IR images, and if the SNR is not already computed or a signal provided by the IR module 1514 for example.

The image processing system 1500 may have one or more of processors 1530 which may include a dedicated image signal processor (ISP) 1532 such as the Intel Atom, memory stores 1544 with RAM, cache, and/or other memory types, one or more displays 1534, encoder 1548, and antenna 1540. In one example implementation, the image processing system 1500 may have the display 1534, at least one processor 1530 communicatively coupled to the display, at least one memory 1544 communicatively coupled to the processor, and having a buffer 1546 by one example for storing image data and other data related to projector unit 1506 and/or imaging device 1502. The encoder 1548 and antenna 1540 may be provided to compress the modified image date for transmission to other devices that may display or store the image. It will be understood that the image processing system 1500 may also include a decoder (or encoder 1548 may include a decoder) to receive and decode image data for processing by the system 1500. Otherwise, the processed image 1542 may be displayed on display 1534 or stored in memory 1544. As illustrated, any of these components may be capable of communication with one another and/or communication with portions of logic modules 1504, projector unit 1506, and/or imaging device 1502. Thus, processors 1530 may be communicatively coupled to the imaging device 1502, projector unit 1506, and the logic modules 1504 for operating those components. By one approach, although image processing system 1500, as shown in FIG. 15, may include one particular set of blocks or actions associated with particular components, units, or modules, these blocks or actions may be associated with different components, units, or modules than the particular component, unit, or module illustrated here.

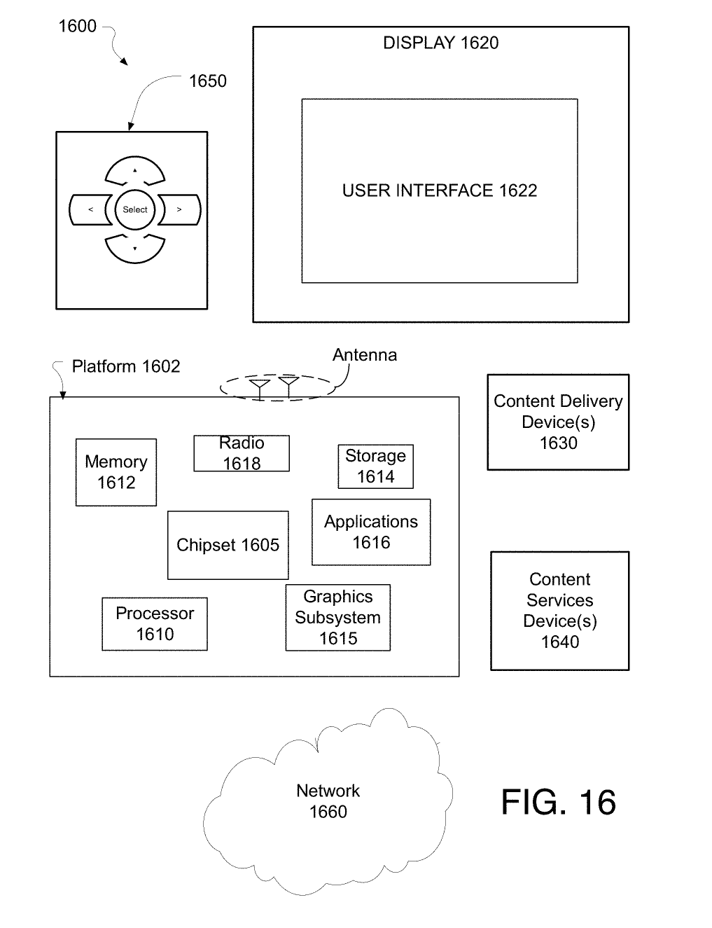

Referring to FIG. 16, an example system 1600 in accordance with the present disclosure operates one or more aspects of the image processing systems described herein and may operate or include system 1500. It will be understood from the nature of the system components described below that such components may be associated with, or used to operate, certain part or parts of the image processing system described above. In various implementations, system 1600 may be a media system although system 1600 is not limited to this context. For example, system 1600 may be incorporated into a digital still camera, digital video camera, mobile device with camera or video functions such as an imaging phone, webcam, personal computer (PC), laptop computer, ultra-laptop computer, tablet, touch pad, portable computer, handheld computer, palmtop computer, personal digital assistant (PDA), cellular telephone, combination cellular telephone/PDA, television, smart device (e.g., smart phone, smart tablet or smart television), mobile internet device (MID), messaging device, data communication device, dedicated access authorization device, physical lock device, face login device, object detection device, and so forth.

In various implementations, system 1600 includes a platform 1602 coupled to a display 1620. Platform 1602 may receive content from a content device such as content services device(s) 1630 or content delivery device(s) 1640 or other similar content sources. A navigation controller 1650 including one or more navigation features may be used to interact with, for example, platform 1602 and/or display 1620. Each of these components is described in greater detail below.

In various implementations, platform 1602 may include any combination of a chipset 1605, processor 1610, memory 1612, storage 1614, graphics subsystem 1615, applications 1616 and/or radio 1618. Chipset 1605 may provide intercommunication among processor 1610, memory 1612, storage 1614, graphics subsystem 1615, applications 1616 and/or radio 1618. For example, chipset 1605 may include a storage adapter (not depicted) capable of providing intercommunication with storage 1614.

Processor 1610 may be implemented as a Complex Instruction Set Computer (CISC) or Reduced Instruction Set Computer (RISC) processors; x86 instruction set compatible processors, multi-core, or any other microprocessor or central processing unit (CPU). In various implementations, processor 1610 may be dual-core processor(s), dual-core mobile processor(s), and so forth.

Memory 1612 may be implemented as a volatile memory device such as, but not limited to, a Random Access Memory (RAM), Dynamic Random Access Memory (DRAM), or Static RAM (SRAM).

Storage 1614 may be implemented as a non-volatile storage device such as, but not limited to, a magnetic disk drive, optical disk drive, tape drive, an internal storage device, an attached storage device, flash memory, battery backed-up SDRAM (synchronous DRAM), and/or a network accessible storage device. In various implementations, storage 1614 may include technology to increase the storage performance enhanced protection for valuable digital media when multiple hard drives are included, for example.

Graphics subsystem 1615 may perform processing of images such as still or video for display. Graphics subsystem 1615 may be a graphics processing unit (GPU) or a visual processing unit (VPU), for example. An analog or digital interface may be used to communicatively couple graphics subsystem 1615 and display 1620. For example, the interface may be any of a High-Definition Multimedia Interface, Display Port, wireless HDMI, and/or wireless HD compliant techniques. Graphics subsystem 1615 may be integrated into processor 1610 or chipset 1605. In some implementations, graphics subsystem 1615 may be a stand-alone card communicatively coupled to chipset 1605.

The graphics and/or video processing techniques described herein may be implemented in various hardware architectures. For example, graphics and/or video functionality may be integrated within a chipset. Alternatively, a discrete graphics and/or video processor may be used. As still another implementation, the graphics and/or video functions may be provided by a general purpose processor, including a multi-core processor. In further implementations, the functions may be implemented in a consumer electronics device.

Radio 1618 may include one or more radios capable of transmitting and receiving signals using various suitable wireless communications techniques. Such techniques may involve communications across one or more wireless networks. Example wireless networks include (but are not limited to) wireless local area networks (WLANs), wireless personal area networks (WPANs), wireless metropolitan area network (WMANs), cellular networks, and satellite networks. In communicating across such networks, radio 1618 may operate in accordance with one or more applicable standards in any version.

In various implementations, display 1620 may include any television type monitor or display. Display 1620 may include, for example, a computer display screen, touch screen display, video monitor, television-like device, and/or a television. Display 1620 may be digital and/or analog. In various implementations, display 1620 may be a holographic display. Also, display 1620 may be a transparent surface that may receive a visual projection. Such projections may convey various forms of information, images, and/or objects. For example, such projections may be a visual overlay for a mobile augmented reality (MAR) application. Under the control of one or more software applications 1616, platform 1602 may display user interface 1622 on display 1620.

In various implementations, content services device(s) 1630 may be hosted by any national, international and/or independent service and thus accessible to platform 1602 via the Internet, for example. Content services device(s) 1630 may be coupled to platform 1602 and/or to display 1620. Platform 1602 and/or content services device(s) 1630 may be coupled to a network 1660 to communicate (e.g., send and/or receive) media information to and from network 1660. Content delivery device(s) 1640 also may be coupled to platform 1602 and/or to display 1620.

In various implementations, content services device(s) 1630 may include a cable television box, personal computer, network, telephone, Internet enabled devices or appliance capable of delivering digital information and/or content, and any other similar device capable of unidirectionally or bidirectionally communicating content between content providers and platform 1602 and/display 1620, via network 1660 or directly. It will be appreciated that the content may be communicated unidirectionally and/or bidirectionally to and from any one of the components in system 1600 and a content provider via network 1660. Examples of content may include any media information including, for example, video, music, medical and gaming information, and so forth.

Content services device(s) 1630 may receive content such as cable television programming including media information, digital information, and/or other content. Examples of content providers may include any cable or satellite television or radio or Internet content providers. The provided examples are not meant to limit implementations in accordance with the present disclosure in any way.

In various implementations, platform 1602 may receive control signals from navigation controller 1650 having one or more navigation features. The navigation features of controller 1650 may be used to interact with user interface 1622, for example. In implementations, navigation controller 1650 may be a pointing device that may be a computer hardware component (specifically, a human interface device) that allows a user to input spatial (e.g., continuous and multi-dimensional) data into a computer. Many systems such as graphical user interfaces (GUI), and televisions and monitors allow the user to control and provide data to the computer or television using physical gestures.

Movements of the navigation features of controller 1650 may be replicated on a display (e.g., display 1620) by movements of a pointer, cursor, focus ring, or other visual indicators displayed on the display. For example, under the control of software applications 1616, the navigation features located on navigation controller 1650 may be mapped to virtual navigation features displayed on user interface 1622, for example. In implementations, controller 1650 may not be a separate component but may be integrated into platform 1602 and/or display 1620. The present disclosure, however, is not limited to the elements or in the context shown or described herein.

In various implementations, drivers (not shown) may include technology to enable users to instantly turn on and off platform 1602 like a television with the touch of a button after initial boot-up, when enabled, for example. Program logic may allow platform 1602 to stream content to media adaptors or other content services device(s) 1630 or content delivery device(s) 1640 even when the platform is turned “off.” In addition, chipset 1605 may include hardware and/or software support for 8.1 surround sound audio and/or high definition (7.1) surround sound audio, for example. Drivers may include a graphics driver for integrated graphics platforms. In implementations, the graphics driver may comprise a peripheral component interconnect (PCI) Express graphics card.

In various implementations, any one or more of the components shown in system 1600 may be integrated. For example, platform 1602 and content services device(s) 1630 may be integrated, or platform 1602 and content delivery device(s) 1640 may be integrated, or platform 1602, content services device(s) 1630, and content delivery device(s) 1640 may be integrated, for example. In various implementations, platform 1602 and display 1620 may be an integrated unit. Display 1620 and content service device(s) 1630 may be integrated, or display 1620 and content delivery device(s) 1640 may be integrated, for example. These examples are not meant to limit the present disclosure.

In various implementations, system 1600 may be implemented as a wireless system, a wired system, or a combination of both. When implemented as a wireless system, system 1600 may include components and interfaces suitable for communicating over a wireless shared media, such as one or more antennas, transmitters, receivers, transceivers, amplifiers, filters, control logic, and so forth. An example of wireless shared media may include portions of a wireless spectrum, such as the RF spectrum and so forth. When implemented as a wired system, system 1600 may include components and interfaces suitable for communicating over wired communications media, such as input/output (I/O) adapters, physical connectors to connect the I/O adapter with a corresponding wired communications medium, a network interface card (NIC), disc controller, video controller, audio controller, and the like. Examples of wired communications media may include a wire, cable, metal leads, printed circuit board (PCB), backplane, switch fabric, semiconductor material, twisted-pair wire, co-axial cable, fiber optics, and so forth.

Platform 1602 may establish one or more logical or physical channels to communicate information. The information may include media information and control information. Media information may refer to any data representing content meant for a user. Examples of content may include, for example, data from a voice conversation, videoconference, streaming video, electronic mail (“email”) message, voice mail message, alphanumeric symbols, graphics, image, video, text and so forth. Data from a voice conversation may be, for example, speech information, silence periods, background noise, comfort noise, tones and so forth. Control information may refer to any data representing commands, instructions or control words meant for an automated system. For example, control information may be used to route media information through a system, or instruct a node to process the media information in a predetermined manner. The implementations, however, are not limited to the elements or in the context shown or described in FIG. 16.

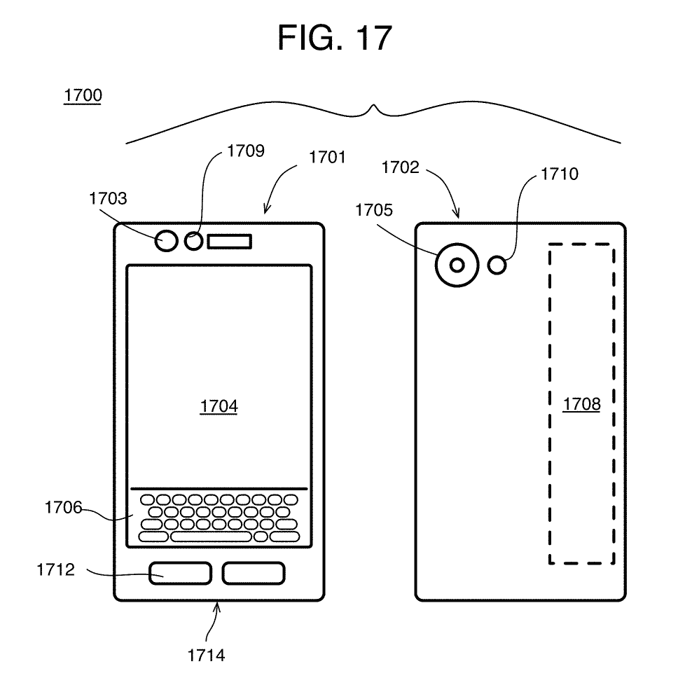

Referring to FIG. 17, a small form factor device 1700 is one example of the varying physical styles or form factors in which systems 1500 or 1600 may be embodied. By this approach, device 1500 may be implemented as a mobile computing device having wireless capabilities. A mobile computing device may refer to any device having a processing system and a mobile power source or supply, such as one or more batteries, for example.

As described above, examples of a mobile computing device may include a digital still camera, digital video camera, mobile devices with camera or video functions such as imaging phones, webcam, personal computer (PC), laptop computer, ultra-laptop computer, tablet, touch pad, portable computer, handheld computer, palmtop computer, personal digital assistant (PDA), cellular telephone, combination cellular telephone/PDA, television, smart device (e.g., smart phone, smart tablet or smart television), mobile internet device (MID), messaging device, data communication device, and so forth.

Examples of a mobile computing device also may include computers that are arranged to be worn by a person, such as a wrist computer, finger computer, ring computer, eyeglass computer, belt-clip computer, arm-band computer, shoe computers, clothing computers, and other wearable computers. In various implementations, for example, a mobile computing device may be implemented as a smart phone capable of executing computer applications, as well as voice communications and/or data communications. Although some implementations may be described with a mobile computing device implemented as a smart phone by way of example, it may be appreciated that other implementations may be implemented using other wireless mobile computing devices as well. The implementations are not limited in this context.

As shown in FIG. 17, device 1700 may include a housing with a front 1701 and a back 1702. Device 1700 includes a display 1704, an input/output (I/O) device 1706, and an integrated antenna 1708. Device 1700 also may include navigation features 1712. I/O device 1706 may include any suitable I/O device for entering information into a mobile computing device. Examples for I/O device 1706 may include an alphanumeric keyboard, a numeric keypad, a touch pad, input keys, buttons, switches, microphones, speakers, voice recognition device and software, and so forth. Information also may be entered into device 1700 by way of microphone 1714, or may be digitized by a voice recognition device. As shown, device 1700 may include a camera 1705 (e.g., including at least one lens, aperture, and imaging sensor) and a flash 1710 integrated into back 1702 (or elsewhere) of device 1700. The implementations are not limited in this context.

Various forms of the devices and processes described herein may be implemented using hardware elements, software elements, or a combination of both. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth. Examples of software may include software components, programs, applications, computer programs, application programs, system programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. Determining whether an implementation is implemented using hardware elements and/or software elements may vary in accordance with any number of factors, such as desired computational rate, power levels, heat tolerances, processing cycle budget, input data rates, output data rates, memory resources, data bus speeds and other design or performance constraints.

One or more aspects of at least one implementation may be implemented by representative instructions stored on a machine-readable medium which represents various logic within the processor, which when read by a machine causes the machine to fabricate logic to perform the techniques described herein. Such representations, known as “IP cores” may be stored on a tangible, machine readable medium and supplied to various customers or manufacturing facilities to load into the fabrication machines that actually make the logic or processor.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

The following examples pertain to further implementations.

By one example implementation, an illuminator comprises a substrate; and multiple arrays of vertical cavity semiconductor emitting lasers (VCSELs) on the substrate, wherein at least one of the arrays having VCSELs with apertures of a different size then a size of the apertures of VCSELs of at least one other of the arrays so that the at least one array and at least one other array emit light in different wavelengths.

By another implementation, this illuminator may comprise four to six of the arrays, wherein each of the arrays has VCSELs with a different aperture size than the aperture size of VCSELs of the other arrays, wherein one of the arrays has VCSELs with apertures of about 2 μm and another array of VCSELs with apertures of about 3 or 4 μm, wherein the largest aperture is 4 μm for any one of the arrays. By an alternative, the illuminator comprises four of the arrays arranged 2×2 and where each diagonally arranged pair of arrays has the same aperture size and that is different than the other diagonally arranged pair of arrays. The illuminator also comprising a polarizing metalayer disposed on individual VCSELs in the arrays, wherein each metalayer having an arrangement of spaced sub-wavelength light scattering posts elongated in top view to act as polarizers, and wherein the metalayers on VCSELs in one array have posts generally extending in a different direction than the posts of another of the arrays, wherein arrays with the same aperture size have metalayers with posts elongated in a same first direction while arrays with a different aperture size have metalayers with posts elongated in a different direction than the first direction, wherein each coupling of metalayer and VCSEL the metalayer is upon is arranged to cooperatively form a predetermined far-field light intensity radiation pattern.

By a further implementation, another illuminator may comprise a plurality of arrays of vertical-cavity surface emitting lasers (VCSELs) each VCSEL having a light emitting surface; and a polarizing metalayer disposed on individual VCSELs and each metalayer having a plurality of spaced sub-wavelength light scattering posts to receive light from the light emitting surface and emit the light, wherein the posts of the metalayers on VCSELs of one of the arrays is elongated in top view and in a direction that is different than the elongated direction of posts of metalayers on VCSELs on at least one other of the arrays, and wherein all posts on the same array are elongated in the same direction.

By another implementation, this illuminator may comprise wherein the posts are rectangular in top view, wherein a polarizing length to width ratio in top view of the posts is about 3:1 to 6:1, and the illuminator comprising four of the arrays arranged 2×2 and where each diagonally arranged pair of arrays has the posts extending in the same elongated direction and that is different than the direction on the other diagonally arranged pair of arrays, wherein arrays with VCSELs having the same aperture size have metalayers with posts elongated in a same first direction in top view while arrays with a different VCSEL aperture size have metalayers with posts elongated in a different direction than the first direction.

A method of emitting light to capture images, comprises emitting IR or NIR light from an illuminator having a plurality of arrays of vertical-cavity surface emitting lasers (VCSELs) emitting light; and emitting light at at least one of the arrays with VCSELs of one or more aperture sizes different than the aperture size or sizes of VCSELs of at least one other of the arrays so that the at least one array emits light at a dominant wavelength different than the dominant wavelength of the at least one other array.

The method also may include at least one array with VCSELs having apertures of about 2 μm and at least one array with VCSELs having an aperture size larger than 2 μm, wherein all of the arrays have the same number of VCSELs in the same row and column arrangement of VCSELs, and the method comprising emitting the light through metalayers with posts on the VCSELs wherein either (a) arrays with VCSELs having the same aperture size have metalayers with posts elongated in the same first direction in top view while arrays with a different VCSEL aperture size have metalayers with posts elongated in a different direction than the first direction, or (b) wherein arrays with VCSELs having the same aperture size have metalayers with posts elongated in different directions in top view from array to array while arrays with a different VCSEL aperture size have metalayers with posts elongated in a same direction.

As another implementation, a method of forming a light emitting device comprises forming an infra-red (IR) or near-infra-red (NIR) illuminator comprising multiple arrays of vertical-cavity surface emitting lasers (VCSELs) having a layer with a light emitting surface; and forming the VCSELs of one array with apertures that are a different size than apertures of VCSELs of at least one other array so that the dominant wavelength of the one array and other array is sufficiently different to reduce speckle.

The method also may comprise forming an upper DBR layer that forms a light emitting surface of the VCSELs and with a width that establishes the aperture of the VCSEL; forming a metalayer having a plurality of spaced light scattering metalayer posts disposed to receive light from the light emitting surface and redirect the light; and forming the metalayer posts with an elongated shape to polarize the light in a certain direction comprising the metalayer posts elongated in top view in one direction for VCSELs of one of the arrays and the metalayers elongated in a different direction in top view on another of the arrays; forming the one and different direction to be perpendicular to each other; arranging the posts to emit light with a wavelength of λ, and the method comprising forming the posts with a height and length of about λ/2, and a width of λ/10 wherein the length is parallel to a direction of an applied electric field on one array and perpendicular to the direction of the applied electric field on another array; and forming the posts by using lithography.

In a further example, at least one machine readable medium may include a plurality of instructions that in response to being executed on a computing device, causes the computing device to perform the method according to any one of the above examples.

In a still further example, an apparatus may include means for performing the methods according to any one of the above examples.

The above examples may include specific combination of features. However, the above examples are not limited in this regard and, in various implementations, the above examples may include undertaking only a subset of such features, undertaking a different order of such features, undertaking a different combination of such features, and/or undertaking additional features than those features explicitly listed. For example, all features described with respect to any example methods herein may be implemented with respect to any example apparatus, example systems, and/or example articles, and vice versa.

What is claimed is:

1. An illuminator comprising:
a substrate; and
multiple arrays of vertical cavity semiconductor emitting lasers (VCSELs) on the substrate,
wherein at least one of the arrays having VCSELs with apertures of a different size then a size of the apertures of VCSELs of at least one other of the arrays so that the at least one array and at least one other array emit light in different wavelengths.

2. The illuminator of claim 1 comprising four to six of the arrays.

3. The illuminator of claim 1 wherein each of the arrays has VCSELs with a different aperture size than the aperture size of VCSELs of the other arrays.

4. The illuminator of claim 1 wherein one of the arrays has VCSELs with apertures of about 2 μm and another array of VCSELs with apertures of about 3 or 4 μm.

5. The illuminator of claim 1 wherein the largest aperture is 4 μm for any one of the arrays.

6. The illuminator of claim 1 comprising four of the arrays arranged 2×2 and where each diagonally arranged pair of arrays has the same aperture size and that is different than the other diagonally arranged pair of arrays.

7. The illuminator of claim 1 comprising a polarizing metalayer disposed on individual VCSELs in the arrays, wherein each metalayer having an arrangement of spaced sub-wavelength light scattering posts elongated in top view to act as polarizers, and wherein the metalayers on VCSELs in one array have posts generally extending in a different direction than the posts of another of the arrays.

8. The illuminator of claim 7 wherein arrays with the same aperture size have metalayers with posts elongated in a same first direction while arrays with a different aperture size have metalayers with posts elongated in a different direction than the first direction.

9. The illuminator of claim 7 wherein each coupling of metalayer and VCSEL the metalayer is upon is arranged to cooperatively form a predetermined far-field light intensity radiation pattern.

10. An illuminator, comprising:
a plurality of arrays of vertical-cavity surface emitting lasers (VCSELs) each VCSEL having a light emitting surface; and
a polarizing metalayer disposed on individual VCSELs and each metalayer having a plurality of spaced sub-wavelength light scattering posts to receive light from the light emitting surface and emit the light,
wherein the posts of the metalayers on VCSELs of one of the arrays is elongated in top view and in a direction that is different than the elongated direction of posts of metalayers on VCSELs on at least one other of the arrays, and wherein all posts on the same array are elongated in the same direction.

11. The illuminator of claim 10 wherein the posts are rectangular in top view.

12. The illuminator of claim 10 wherein a polarizing length to width ratio in top view of the posts is about 3:1 to 6:1.

13. The illuminator of claim 10 comprising four of the arrays arranged 2×2 and where each diagonally arranged pair of arrays has the posts extending in the same elongated direction and that is different than the direction on the other diagonally arranged pair of arrays.

14. The illuminator of claim 10 wherein arrays with VCSELs having the same aperture size have metalayers with posts elongated in a same first direction in top view while arrays with a different VCSEL aperture size have metalayers with posts elongated in a different direction than the first direction.

15. A method of emitting light to capture images, comprising:
emitting IR or NIR light from an illuminator having a plurality of arrays of vertical-cavity surface emitting lasers (VCSELs) emitting light; and
emitting light at at least one of the arrays with VCSELs of one or more aperture sizes different than the aperture size or sizes of VCSELs of at least one other of the arrays so that the at least one array emits light at a dominant wavelength different than the dominant wavelength of the at least one other array.

16. The method of claim 15 comprising at least one array with VCSELs having apertures of about 2 μm and at least one array with VCSELs having an aperture size larger than 2 μm.

17. The method of claim 15 wherein all of the arrays have the same number of VCSELs in the same row and column arrangement of VCSELs.

18. The method of claim 15 comprising emitting the light through metalayers with posts on the VCSELs wherein arrays with VCSELs having the same aperture size have metalayers with posts elongated in the same first direction in top view while arrays with a different VCSEL aperture size have metalayers with posts elongated in a different direction than the first direction.

19. The method of claim 15 comprising emitting the light through metalayers with posts on the VCSELs wherein arrays with VCSELs having the same aperture size have metalayers with posts elongated in different directions in top view from array to array while arrays with a different VCSEL aperture size have metalayers with posts elongated in a same direction.

20. A method of forming a light emitting device comprising:
forming an infra-red (IR) or near-infra-red (NIR) illuminator comprising multiple arrays of vertical-cavity surface emitting lasers (VCSELs) having a layer with a light emitting surface; and
forming the VCSELs of one array with apertures that are a different size than apertures of VCSELs of at least one other array so that the dominant wavelength of the one array and other array is sufficiently different to reduce speckle.

21. The method of claim 20 comprising forming an upper DBR layer that forms a light emitting surface of the VCSELs and with a width that establishes the aperture of the VCSEL.

22. The method of claim 20 comprising forming a metalayer having a plurality of spaced light scattering metalayer posts disposed to receive light from the light emitting surface and redirect the light; and
forming the metalayer posts with an elongated shape to polarize the light in a certain direction comprising the metalayer posts elongated in top view in one direction for VCSELs of one of the arrays and the metalayers elongated in a different direction in top view on another of the arrays.

23. The method according to claim 22 comprising forming the one and different direction to be perpendicular to each other.

24. The method of claim 22 comprising arranging the posts to emit light with a wavelength of λ, and the method comprising forming the posts with a height and length of about λ/2, and a width of λ/10 wherein the length is parallel to a direction of an applied electric field on one array and perpendicular to the direction of the applied electric field on another array.

25. The method of claim 20 comprising forming the posts by using lithography.
